(19) United States
(12) Patent Application Publication
(10) Pub. No.: US 2020/0187390 A1
(43) Pub. Date: Jun. 11, 2020

(54) Control Unit for Evaluating Signals for a Vehicle and Manufacturing Process for a Control Unit for Evaluating Signals for a Vehicle

(71) Applicant: ZF Friedrichshafen AG, Friedrichshafen (DE)

(72) Inventors: Maximilian Olpp, Friedrichshafen (DE); Danny Grusser, Tettnang (DE); Boris Heberle, Friedrichshafen (DE); Viktor Rakoczi, Immenstaad am Bodensee (DE)

(21) Appl. No.: 16/708,666

(22) Filed: Dec. 10, 2019

(30) Foreign Application Priority Data
Dec. 11, 2018 (DE) 10 2018 221 420.4

(51) Int. Cl. H05K 7/20; H05K 1/02; H05K 3/00

(52) U.S. Cl. CPC H05K 7/20863; H05K 1/0204; H05K 3/0061; H05K 1/0209

(57) ABSTRACT

A control unit (SG) is provided for evaluating signals for a vehicle (FZ), including at least two printed circuit plates (PB, CB) equipped with modules to be cooled, which are positioned opposite one another and are covered by cooling structures (KS1, KS2) on the opposed sides. Sidewalls (SW) are arranged at a right angle with respect to the cooling structures (KS1, KS2) and, together with the cooling structures, form a cooling duct. A fluid is movable through the cooling duct for heat dissipation. Seal(s) are provided between the sidewalls and the cooling structures.

### CROSS-REFERENCE TO RELATED APPLICATION

The present application is related and has right of priority to German Patent Application No. 10 2018 221 420.4 filed on Dec. 11, 2018, the entirety of which is incorporated by reference for all purposes.

### FIELD OF THE INVENTION

The invention is directed generally to a control unit for evaluating signals for a vehicle and to a manufacturing process for a control unit for evaluating signals for a vehicle.

### BACKGROUND

DE 10 2017 002 601 A1 describes an electronic control unit for a motor vehicle, in which a gas cooling duct is provided for conducting a compressed gas. This gas cooling duct is connected to a first electronic control unit in a heat-conducting manner and is designed for separating the compressed gas from the first electronic control unit. The gas cooling duct includes an expansion section, in which a flow cross-section of the gas cooling duct enlarges in order to expand and cool the compressed gas for the purpose of cooling the first electronic control unit. In particular, it is provided that the gas cooling duct is located between two printed circuit plates, whose components face one another.

### SUMMARY OF THE INVENTION

The control unit according to example aspects of the invention for evaluating signals for a vehicle has the advantage over the prior art that the printed circuit plates equipped with modules to be cooled are each covered by cooling structures. In addition, sidewalls are also provided, which are arranged at a right angle with respect to the cooling structures and, together with the cooling structures, form the cooling duct. Therefore, a well-enclosed cooling duct is implemented. In addition, it is provided that a fluid is moved through the cooling duct for the purpose of heat dissipation. Therefore, in contrast to the prior art, convection cooling is provided and compression of a gas and subsequent expansion, which would represent a considerable outlay, are not provided. In this case, the fluid, i.e., air or a liquid, can be moved through the cooling duct, for example, in the case of air, with the aid of fans drawing in the ambient air, in order to dissipate the heat—which is generated by the modules on the printed circuit plates—via the particular cooling structure. Finally, sealing means are also provided between the cooling structures and the sidewalls. Therefore, the fluid flows through a hermetically sealed cooling duct.

The control unit for evaluating signals for a vehicle is, for example, a control unit, which processes highly diverse sensor signals in a vehicle, for example, a passenger car, and, on the basis thereof, derives control signals for an actuator system. For this purpose, the control unit can include one or more processors, in particular graphic processors, but also microprocessors or other processing units, in order to evaluate the signals. The control unit can also include, in particular, a housing, which is made of plastic, metal, or a combination thereof. This means, the control unit can receive sensor signals or preprocessed sensor signals via highly diverse communication channels, evaluates these with the aid of computing power and then, on the basis thereof, derives the control signals. Therefore, signals are either raw data from sensors or also preprocessed sensor signals, in the case of which intermediate results have already been obtained, or also a mixture thereof. The sensor signals can be transmitted via point-to-point or bus connections, but also via optical lines or radio or wireless links.

The printed circuit plates are electrical printed circuit plates or printed circuit boards (PCBs), which include strip conductors, in order to connect the modules located on the printed circuit plates to one another. The printed circuit plates can be formed, in particular, using a multilayer technology. Preferably, one of the at least two printed circuit plates is the lower printed circuit plate and the other is the upper printed circuit plate. According to a preferred embodiment, there is a lower printed circuit plate, which is positioned opposite three upper printed circuit plates.

The modules, which are electronic modules, such as processors, application-specific integrated circuits (ASICs), or power modules, emit heat during operation. Therefore, these modules are to be cooled and the heat is to be appropriately dissipated. The printed circuit plates are positioned opposite one another in the control unit, i.e., the modules on the two printed circuit plates face one another. These printed circuit plates, which are separated, for example, by a distance of four centimeters (4 cm), are covered by cooling structures, however. The extent of coverage can be complete, so that a complete structure is attached over the particular printed circuit plate. For example, these cooling structures can be detachably attached on the respective printed circuit plates, for example, with the aid of a bolted or fastened connection.

The extent of coverage by the cooling structures can be complete, as mentioned above. This means, the printed circuit plate is completely or also only partially covered by the cooling structure.

Sidewalls are understood to be structures made, for example, of aluminum, which enclose the space around the printed circuit plates and the cooling structures, between the cooling structures at a right angle with respect thereto. Therefore, the duct is formed. These sidewalls can enclose, in particular, a fan downstream from the printed circuit plates, which draws in or blows the air for dissipating the heat. In particular, these sidewalls are open toward two sides, so that the air or the fluid can flow through the cooling duct. It is possible that the two openings of the cooling duct lie on a plane or one of the openings is arranged at a right angle to the other opening. A fluid is therefore moved through the cooling duct for the purpose of heat dissipation. In addition to air, water or another liquid can also be utilized. The sidewalls can preferably be formed as one piece with one of the cooling structures. In particular, the cooling structure on the lower printed circuit plate is suitable for the integral design with the sidewalls.

The sealing can be implemented with the aid of the assembly or, subsequent thereto, with the aid of an extrusion-coating. Rubber seals, in particular, can be utilized during the assembly.

The manufacturing process according to example aspects of the invention for a control unit for evaluating signals for a vehicle is also provided. The lower printed circuit plate is mounted on the housing bottom. Subsequent thereto, the attachment of the lower cooling structure on the lower printed circuit plate takes place. The lower cooling structure is then connected to an upper cooling structure. The upper printed circuit plate is attached to the upper cooling structure. Finally, the housing cover is mounted on the upper printed circuit plate. Preferably, the mounting, the attachment, and the connection take place with the aid of bolted connections. Other detachable and non-detachable connections are also possible, however. In particular, it is possible to provide further manufacturing steps between the steps or before and/or after the steps.

It is advantageous that the fluid is forced, suctioned, blown, or pumped. In particular, suctioning or blowing is advantageous for air or another gas or gas mixture, and pumping is advantageous for a liquid such as water. A gas can also be pumped, however.

In an advantageous example embodiment, ambient air is drawn in and, in so doing, is moved through the cooling duct. Therefore, it is necessary to connect the cooling duct to the ambient air on the input-end and on the output-end.

In addition, it is provided that the two cooling structures each include, on the opposed sides, structures for surface enlargement and/or for generating turbulence and, on the sides facing the printed circuit plates, cooling structures for contact with at least one part of the components to be cooled. Therefore, the cooling structures are defined in such a way that the cooling structures have such structures for surface enlargement and/or for generating turbulence in the cooling duct, in order to generate more surface area and to be able to better dissipate the heat. A further function of the structures for surface enlargement and/or for generating turbulence is that such structures result in a turbulent flow, in order to break through a boundary layer, which forms in the fluid around the structures. This boundary layer prevents the effective dissipation of heat.

The cooling structures for contact with at least one part of the components to be cooled are provided on the side facing the printed circuit plate. Such cooling structures contact the component directly, in order to be able to absorb or conduct the heat onto the cooling structures, so that the heat can then flow further to the structures and be dissipated there. It is also possible that the cooling structures contact the components indirectly, in that the heat flows from the components through the printed circuit plate to a region, which is then connected to the cooling structure.

These cooling structures can be geometrically manufactured in such a way that the cooling structures come into contact with the components or only comprise an air gap with respect to the components and then the air gap is filled, for example, with a thermal interface material, for example, a thermal gap filler. That is, the air gap is filled with the thermal interface material. Therefore, in particular, a force-free contacting of the components for the purpose of heat dissipation is also possible. Generally, a gap filler is understood to be a paste-like compound having increased thermal conductivity. A particularly high increase of the thermal conductivity can take place by adding metallic or ceramic particles.

It is provided that the cooling structures can be heat sinks, fins (e.g., straight fins), pin fins, and/or hedgehogs. These are designs that have proven suitable as such structures.

In addition, the two printed circuit plates may be connected by at least one electrical connection outside the sidewalls for signal and/or energy transmission. Since the cooling duct is now provided between the printed circuit plates but the two plates must also be connected in order to be able to transfer signals and/or electrical energy to each other, an electrical connection is provided outside the cooling duct. This electrical connection can preferably be a further printed circuit plate, which is arranged at a right angle with respect to the other two printed circuit plates, for example, in a pocket next to the sidewalls, in particular a sidewall of the cooling duct.

In addition, on a first, lower printed circuit plate, three cooling ducts may be formed, in each case, by three further, upper printed circuit plates and their cooling structures, which are arranged next to one another, and associated sidewalls, as well as three further cooling structures on the first printed circuit plate. Therefore, an arrangement is described, which includes not only a single cooling duct, but rather three, because an upper printed circuit plate, which is situated on the large first, lower printed circuit plate, is present three times, in order to be able to redundantly process the sensor signals. Therefore, each cooling duct for each of the further, upper printed circuit plates is separated from one another. Such an overall structure including three cooling ducts for three printed circuit plates, which are located next to one another, is particularly favorable with respect to the signal evaluation, since a sufficient redundancy for the signal processing is then given, which is of the type necessary, for example, in automated driving functions.

In addition, a signal processing module to be cooled may be located on the first, preferably lower printed circuit plate under a processor for processing the signals on the middle further, preferably upper printed circuit plate. With respect to the aforementioned structure including three cooling ducts, a signal processing module is provided on the lower printed circuit plate, which distributes signals to the processors on the upper three printed circuit plates. For reasons of signal integrity, it is therefore important to identically configure the distance to the processors on the upper printed circuit plates, i.e., the lines are equally long. This prevents the processors from processing the signals at different times. In particular, the processor is arranged on the middle printed circuit plate over the signal processing module on the lower printed circuit plate. Optimal conditions for the signal processing are therefore given. The lower signal processing module will namely preferably distribute the incoming sensor signals, as described above, onto the upper processors according to predefined conditions.

In addition, it is provided that the fins of the opposed cooling structures do not engage into or contact each other. Therefore, a tooth system is not present. A good through-flow for the fluid is therefore ensured.

In addition, the fins may be at least partially designed as corrugated fins. These corrugated fins are particularly efficient for heat dissipation because the corrugated fins further increase the surface area that is available, in order to allow the fluid to contact and flow around them. In addition, the corrugated fins induce more turbulence into the flow, as described above.

In addition, the cooling structures may be designed such that the cooling structures contact at least one cooling zone on at least one of the two printed circuit plates for the purpose of heat dissipation. Due, for example, to the size of the modules on a printed circuit plate, the modules may not be contacted directly via the cooling structure, but rather the heat may be conducted via the printed circuit plate itself to cooling zones on the printed circuit plate. There, a contacting or connection can then take place via the cooling structure, in order to ultimately remove this heat from the printed circuit plate.

In addition, the cooling structures may be formed at least primarily of aluminum. Aluminum is a lightweight and thermally conductive material, which can be cost-effectively and easily manufactured.

In addition, a thermal interface material, which thermally couples the cooling structure to the module or to the cooling zone, may be provided for contacting the cooling structure to the modules or also to the cooling zones. Preferably, a thermal gap filler can be utilized for this purpose. As described above, this is a paste that may include silver particles. Equivalent materials for the thermal contacting between the cooling structure and the cooling zone can also be utilized for this purpose, however, such as: heat transfer compounds; heat transfer adhesives; heat transfer pads; and/or latent heat accumulators.

### BRIEF DESCRIPTION OF THE DRAWINGS

Exemplary embodiments of the invention are explained in greater detail in the following description and are represented in the drawings.

In the drawings

FIG. 1 shows a block diagram of the control unit according to example aspects of the invention in the vehicle,

FIG. 2 shows a diagrammatic sectional image of a cooling duct,

FIG. 3 shows a top view of a sidewall structure comprising a part for accommodating a printed circuit plate,

FIG. 4 shows a schematic of the cross-sectional structure of the control unit,

FIG. 5 shows a cross-sectional representation of the upper printed circuit plate including a cooling structure and connected modules on the printed circuit plate through the cooling structure,

FIG. 6 shows an overall structure including three cooling ducts,

FIG. 7 shows a method of the manufacturing process according to example aspects of the invention, and

FIG. 8 diagrammatically shows an example configuration resulting from the manufacturing process according to example aspects of the invention.

### DETAILED DESCRIPTION

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

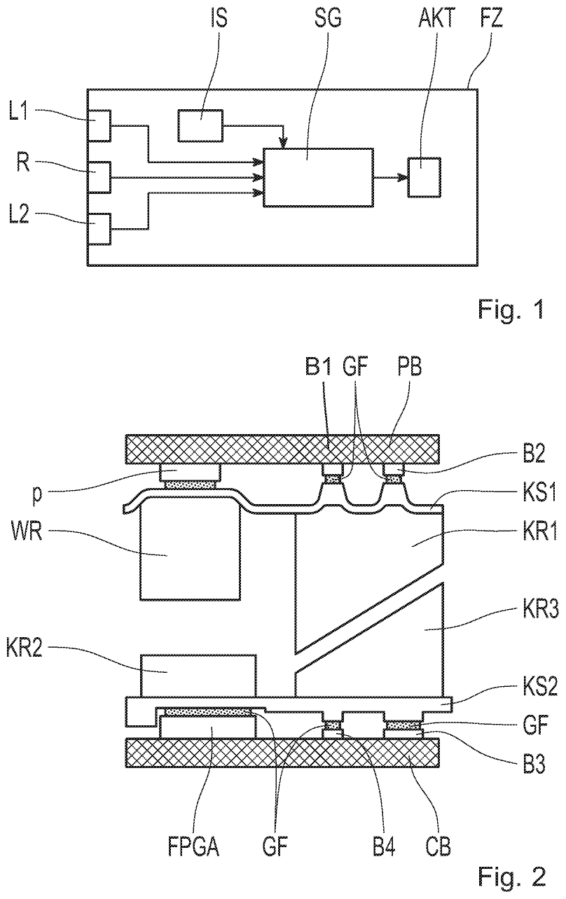

FIG. 1 shows, in a block diagram, a schematic of a vehicle FZ that includes a control unit SG, to which various sensors LIDAR L1 and L2, radar R, and an inertial sensor system IS are connected. It will be understood that one or more additional signal-transmitting modules in the vehicle FZ can be connected to the control unit SG. The control unit SG processes signals from the various sensors and, on the basis thereof, derives control signals for an actuator system. The control unit can utilize, for example, artificial intelligence or deterministic algorithms or a combination thereof for this purpose.

FIG. 2 shows a sectional image of a cooling duct according to example aspects of the invention, which is formed by the cooling structures KS1 and KS2 and, on the sides, by the sidewalls (not represented). Located on the bottom is the carrier board CB, which provides the energy and sensor signals or signal sensoring in the control unit SG. For this purpose, the carrier board CB includes a module FPGA, i.e., a freely programmable gate array, with the aid of which the signals are distributed to the processors P on the performance board PB and further performance boards, if multiple performance boards are involved. Further modules B4 and B3 are provided on the carrier board CB, by way of example. These modules, as is also the case with the FPGA, are contacted by the cooling structure KS2.

The air gap present between the cooling structure KS2 and the modules FPGA, B4, and B3 is filled by the gap filler GF. A force-free connection has therefore been established, since the cooling structure KS2 was aligned with respect to this air gap. This alignment can take place, for example, with the aid of spacers. The cooling structure KS2 includes the cooling fins KR2 and KR3 on the side facing the cooling duct. Cooling fins or fins in general have the task of increasing the surface area around which the fluid flows, so that the heat can be more efficiently dissipated. The performance board PB is arranged on the top and includes modules, at least those represented in the present case by way of example, facing downward in the direction of the carrier board CB.

The processor P, for example, a graphic processor, and further modules B1 and B2 are arranged on the performance board by way of example. The cooling structure KS1 is designed such that the cooling structure KS1 contacts the modules, and a gap filler GF is contained in the air gap between the cooling structure KS1 and each of the modules. A force-free contacting is preferably utilized in this case as well. The cooling structure KS1 also includes a corrugated-fin structure WR, which is directed into the cooling duct, in particular underneath the processor, which converts the most energy and, therefore, generates the most heat, as well as a cooling structure KR1, which includes fins having a conventional shape, in the longitudinal direction of the fluid flow under the modules B1 and B2.

FIG. 3 shows a top view of the structure, which shows only the sidewalls. These sidewalls define the cooling ducts in the horizontal direction. The sidewalls SW include a section L, in which the fan is usually located, in the case of air cooling. The fan draws in the air through the electronics area E. The structure shown in FIG. 2 is located in the electronics area E. The sidewalls SW includes a pocket, in which the printed circuit plate LPX is located. The printed circuit plate LPX transmits signals and electrical energy from the carrier board CB to the performance board PB. This printed circuit plate LPX can therefore be contacted from underneath by the carrier board CB, for example, in the manner of a plug-in card. The sidewalls SW are then placed onto the carrier board CB. The carrier board CB could also be located within the sidewall structure SW, however.

FIG. 4 shows a schematic of the cross-section of the electronics section E of the control unit according to example aspects of the invention. A base, which includes the sidewall structure SW, the carrier board CB, followed by the cooling structure KS2, followed by the cooling structure KS1, assists with forming the cooling duct. An air gap is present between the cooling structures KS1 and KS2. The air gap can be of different sizes. The performance board PB is located on the top of the cooling structure KS1, followed by a cover D for protecting the electronics section E.

FIG. 5 shows a side view of the cooling structure KS1 including the performance board PB. The performance board PB and the cooling structure KS1 are mounted on two columns Pi1 and Pi2. These are mounted, in particular, such that a narrow air gap forms between the cooling structure and its structures with respect to the components B1 and B2. Contact, which transmits a force in order to ensure the reliability of the structure, is therefore not established from the cooling structure to the components B1 and B2. If a force were transmitted, this could negatively influence the components B1 and B2. This air gap between the components B1 and B2 and the cooling structure KS1 is then closed by the gap filler as represented above. The cooling structure KS1 includes the corrugated-fin structure WR under the processor P and the cooling fin structure KR under the components B1 and B2.

FIG. 6 shows an overall structure including the three air ducts. A carrier board CB, on which three performance boards PBL, PBM, and PBR are arranged with the aid, for example, of columns P1 and P2, is provided. The signal processing module FPGA on the carrier board is arranged precisely underneath the processor P of the middle performance board PBM. This is optimal for signal-related reasons. The sidewall structures SW enclose the particular structures, in order to define the cooling ducts. The fans have been omitted in the present case for the sake of simplicity.

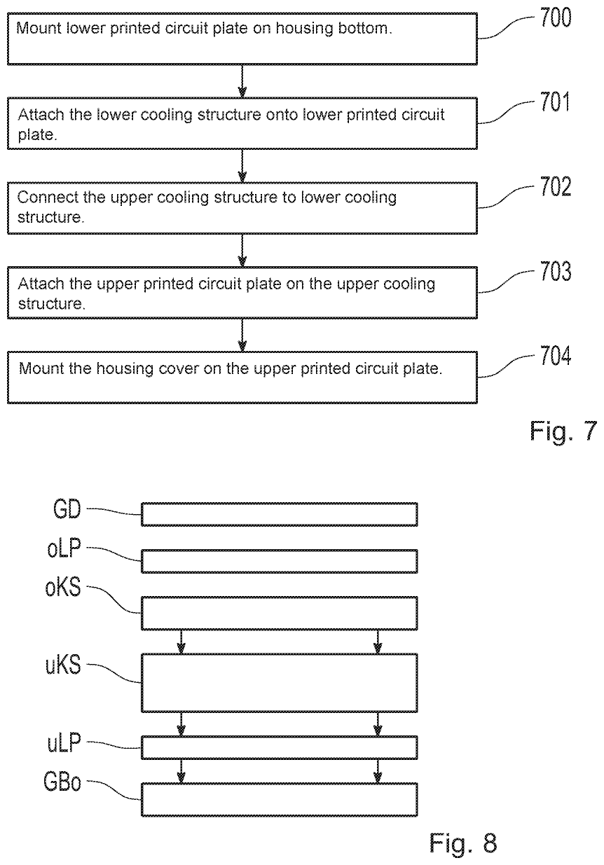

FIG. 7 shows the manufacturing process according to the invention in a flow chart. In method step 700, the printed circuit plate is mounted on the housing bottom. In method step 701, the printed circuit plate is attached to the lower cooling structure. In method step 702, the upper cooling structure is connected to the printed circuit plate. The housing bottom may also be mounted onto the lower cooling structure. In method step 703, the upper printed circuit plate is attached to the upper cooling structure. In method step 704, the housing cover of the control unit is attached to the upper printed circuit plate.

The attachment, mounting, and connection can be preferably implemented with the aid of bolted or fastened connections. The individual elements may include threads, into which the particular bolt for establishing the connection, attachment, or mounting can be screwed. The threads can also be designed in the shape of bushes. Optionally, self-tapping screws can also be utilized.

FIG. 8 diagrammatically shows the configuration resulting from the manufacturing process according to example aspects of the invention. Initially, the upper cooling structure oKS is connected to the lower cooling structure uKS. The lower cooling structure uKS can retain the sidewalls as one piece. In addition, the lower cooling structure uKS as well as the housing bottom GBo and the lower printed circuit plate uLP can be configured for a plurality of cooling ducts. The lower printed circuit plate uLP is then attached to the lower cooling structure uKS. The housing bottom GBo is then bolted onto the lower cooling structure uKS, e.g., with the lower printed circuit plate uLP between the housing bottom GBo and the lower cooling structure uKS. The upper printed circuit plate oLP is preferably bolted in the upper cooling structure oKS. Finally, the housing cover GD is mounted onto the upper printed circuit plate oLP.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

### LIST OF REFERENCE CHARACTERS

FZ vehicle
L1, L2 LIDAR
R radar
IS inertial sensor system
SG control unit
AKT actuator system
PB performance board
GF gap filler
P processor
B1-B4 modules
KS1, KS2 cooling structures
CB carrier board
FPGA signal processing module
WR corrugated fins
KR1 cooling fins
KR2 cooling fins
KR3 cooling fins
LPX printed circuit plate
SW sidewalls
L fan
E electronics unit
D cover
Pi1, Pi2 columns
PBL, PBM, PBR performance boards
700ff method steps
GBo housing bottom
uLP lower printed circuit plate
uKS lower cooling structure
oKS upper cooling structure
oLP upper printed circuit plate
GD housing cover

1-15. (canceled)

16. A control unit (SG) for evaluating signals for a vehicle (FZ), comprising:
at least two printed circuit boards (PB, CB), each of the at least two printed circuit boards (PB, CB) equipped with a respective plurality of coolable modules, the pluralities of coolable modules of the at least two printed circuit boards (PB, CB) facing each other on the at least two printed circuit boards (PB, CB), each plurality of coolable modules of the at least two printed circuit boards (PB, CB) covered by a respective cooling structure (KS1, KS2);
one or more sidewalls (SW) arranged at a right angle with respect to the cooling structures (KS1, KS2), the one or more sidewalls (SW) together with the cooling structures (KS1, KS2) forming a cooling duct, the cooling duct configured for containing a fluid flow through the cooling duct for heat dissipation; and
one or more seals provided between the one or more sidewalls and the cooling structures (KS1, KS2).

17. The control unit of claim 16, wherein the fluid flow is a forced fluid flow that is suctioned, blown, or pumped.

18. The control unit of claim 17, wherein the fluid flow comprises ambient air drawn into the cooling duct.

19. The control unit of claim 16, wherein the cooling structures (KS1, KS2) each comprise a plurality of structures for surface enlargement, for generating turbulence, or for both surface enlargement and generating turbulence (WR, KR), the pluralities of structures facing each other on the cooling structures (KS1, KS2), the cooling structures (KS1, KS2) each comprise at least one cooling structure section that faces a respective one of the at least two printed circuit boards (PB, CB) and connects to at least one portion of the plurality of coolable modules on the respective one of the at least two printed circuit boards (PB, CB).

20. The control unit of claim 16, wherein the cooling structure sections that connects with the at least one portion of the plurality of coolable modules through a thermal interface material that establishes a thermal coupling between the cooling structure sections and the at least one portion of the plurality of coolable modules.

21. The control unit of claim 19, wherein the cooling structures (KS1, KS2) comprises one or more of a plurality of fins, a plurality of pins, and a plurality of flared fins.

22. The control unit of claim 21, wherein the cooling structures (KS1, KS2) do not contact each other.

23. The control unit of claim 21, wherein at least some of the plurality of fins are corrugated fins (WR).

24. The control unit of claim 16, wherein the at least two printed circuit boards (PB, CB) are connected by at least one electrical connection outside the one or more sidewalls (SVV) for signal transmission, energy transmission, or both signal and energy transmission.

25. The control unit of claim 24, wherein the at least one electrical connection comprises an additional printed circuit board (LPX).

26. The control unit of claim 16, wherein:
the at least two printed circuit boards (PB, CB) comprises a lower printed circuit board and three upper printed circuit boards;
three cooling ducts are formed on the lower printed circuit board, each of the three cooling ducts formed with a respective one of the three upper printed circuit boards, the cooling structures of the three upper printed circuit boards, three cooling structures of the lower printed circuit board, and the one or more sidewalls (SW); and
the cooling structures of the three upper printed circuit boards arranged next to one another.

27. The control unit of claim 26, wherein at least one signal processing module (FPGA) is located on the lower printed circuit board (CB) under a processor (P) on a middle one of the three upper printed circuit boards (PBM).

28. The control unit of claim 16, wherein the cooling structures contact at least one cooling zone on at least one of the two printed circuit boards for heat dissipation.

29. The control unit of claim 16, wherein the cooling structures are formed essentially of aluminum.

30. A manufacturing process for a control unit, comprising:
connecting an upper cooling structure to a lower cooling structure;
mounting a lower printed circuit board (CB) on the lower cooling structure;
attaching a housing bottom (GB) on the lower cooling structure;
attaching an upper printed circuit board (PB) on the upper cooling structure; and
mounting a housing cover on the upper printed circuit board (PB), wherein
each of the upper and lower printed circuit boards (PB, CB) is equipped with a respective plurality of coolable modules, the pluralities of coolable modules of the upper and lower printed circuit boards (PB, CB) facing each other on the upper and lower printed circuit boards (PB, CB), the plurality of coolable modules of the upper printed circuit board (PB) covered by the upper cooling structure, the plurality of coolable modules of the lower printed circuit board (CB) covered by the lower cooling structure,
one or more sidewalls (SW) is arranged at a right angle with respect to the upper and lower cooling structures, the one or more sidewalls (SW) together with the upper and lower cooling structures forming a cooling duct, the cooling duct configured for containing a fluid flow through the cooling duct for heat dissipation; and
one or more seals provided between the one or more sidewalls and the upper and lower cooling structures.
